(19) United States
(12) Patent Application Publication
(10) Pub. No.: US 2024/0088011 A1
(43) Pub. Date: Mar. 14, 2024

(54) ELECTRONIC ELEMENT MOUNTING SUBSTRATE

(71) Applicant: KYOCERA Corporation, Kyoto-shi, Kyoto (JP)

(72) Inventors: Futoshi ONIMARU, Kyoto-shi (JP); Joji KAWASAKI, Kyoto-shi (JP); Arata INOMOTO, Kyoto-shi (JP); Atsuo YAMAMOTO, Kyoto-shi (JP)

(73) Assignee: KYOCERA Corporation, Kyoto-shi, Kyoto (JP)

(21) Appl. No.: 18/274,346

(22) PCT Filed: Jan. 25, 2022
(86) PCT No.: PCT/JP2022/002490

§ 371 Date: Jul. 26, 2023

(30) Foreign Application Priority Data
Jan. 29, 2021 (JP) 2021-013863

(51) Int. Cl. H01L 23/498

(52) U.S. Cl. CPC H01L 23/49838; H01L 24/29

(57) ABSTRACT

To reduce the occurrence of scratches in a wide range of a surface of a protruding portion. Solder is firmly fixed to a first metal film. The first metal film has a surface inclined with respect to a first lower surface.

### TECHNICAL FIELD

The present disclosure relates to an electronic element mounting substrate.

### BACKGROUND OF INVENTION

Recently, an electronic element mounting substrate is known. The electronic element mounting substrate includes a substrate having a protruding portion on a lower surface thereof. One example of such an electronic element mounting substrate is disclosed in Patent Document 1.

### CITATION LIST

### Patent Literature

Patent Document 1: JP 2002-299514 A

### SUMMARY

An electronic element mounting substrate according to an aspect of the present disclosure includes a substrate including an upper surface, a first lower surface, a mounting region located on the upper surface and on which an electronic element is to be mounted, and a plurality of protruding portions located on the first lower surface; and at least one first metal film located on a second lower surface that is a lower surface of the plurality of protruding portions, wherein the first metal film comprises a surface inclined with respect to the first lower surface.

### BRIEF DESCRIPTION OF THE DRAWINGS

FIG. 1A is a bottom view illustrating an appearance of an electronic device according to a first embodiment of the present disclosure, FIG. 1B is a vertical cross-sectional view corresponding to a line X1-X1 in FIG. 1A, and FIG. 1C is a variation of FIG. 1B.

FIG. 2A is a cross-sectional view illustrating a layered structure in a first metal film, and

FIG. 2B is a cross-sectional view illustrating a layered structure in a second metal film.

FIG. 3 is a view illustrating an example of a method of providing a gold coating on a surface of a nickel coating, and is a perspective view illustrating a step of packing an intermediate body of an electronic element mounting substrate in a jig.

FIG. 4 is a view illustrating an example of a method of providing the gold coating on the surface of the nickel coating, and is a front view illustrating a step of plating the intermediate body packed in the jig.

FIG. 5 is a top view illustrating a rough trend of a distribution of a film thickness of the gold coating provided on the intermediate body in the step illustrated in FIG. 4.

FIG. 6A is a bottom view illustrating an appearance of an electronic device according to a second embodiment of the present disclosure, and FIG. 6B is a vertical cross-sectional view corresponding to a line X1-X1 in FIG. 6A.

FIG. 7A is a bottom view illustrating an appearance of an electronic device according to a third embodiment of the present disclosure, FIG. 7B is a vertical cross-sectional view corresponding to a line X1-X1 in FIG. 7A, and FIG. 7C is a variation of FIG. 7B.

### DESCRIPTION OF EMBODIMENTS

Hereinafter, embodiments for implementing the present disclosure will be described. For convenience of description, members having the same functions as those described above are denoted by the same reference signs, and the description thereof is not repeated in some cases.

Configuration of Electronic Device

Hereinafter, some exemplary embodiments of the present disclosure will be described with reference to the drawings. In the following description, an electronic device is formed by mounting an electronic element on an electronic element mounting substrate. In the electronic device, any direction may be vertically upward or vertically downward, but for convenience, an orthogonal coordinate system XYZ is defined, and the positive side in the Z direction is defined as upward.

In the present disclosure, a “surface” refers not only to a surface on the front side but also a side surface and a surface on the back side. When only the surface on the front side is referred to, the term “upper surface” is used. When only the surface on the back side is referred to, the term “lower surface” is used.

### First Embodiment

Hereinafter, an electronic device 201 according to the first embodiment of the present disclosure will be described.

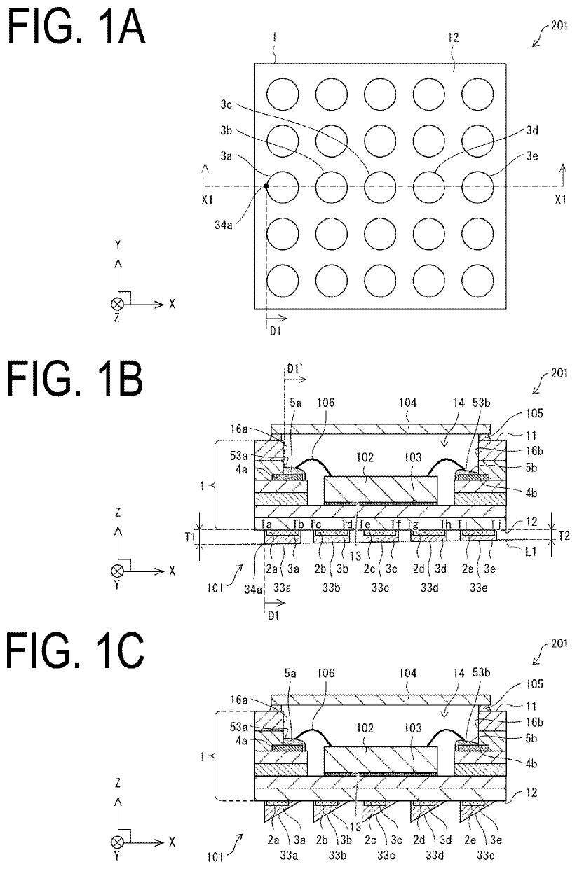

FIG. 1A is a bottom view illustrating the appearance of the electronic device 201 according to the first embodiment of the present disclosure, FIG. 1B is a vertical cross-sectional view corresponding to a line X1-X1 in FIG. 1A, and FIG. 1C is a variation of FIG. 1B.

The electronic device 201 includes an electronic element mounting substrate 101, an electronic element 102, a connection material 103, a lid body 104, a lid bonding material 105, and a bonding wire 106. The electronic element mounting substrate 101 includes a substrate 1, first electrode pads (protruding portions) 2a to 2e, first metal films 3a to 3e, second electrode pads 4a and 4b, and second metal films 5a and 5b.

For the purpose of simplifying the description, the second electrode pads 4a and 4b, the second metal films 5a and 5b, and the bonding wire 106 will be collectively described in the latter half section (second metal film) of the embodiment of the present disclosure. Therefore, in the description of each embodiment before that section, the description of the second electrode pads 4a and 4b, the second metal films 5a and 5b, and the bonding wire 106 will be omitted.

The substrate 1 is a base for mounting the electronic element 102, and has an upper surface 11 and a lower surface (first lower surface) 12. The substrate 1 has a mounting region 13 on which the electronic element 102 is to be mounted. The mounting region 13 is located on the upper surface 11 of the substrate 1. Examples of the material of the substrate 1 include an electrically insulating ceramic and a resin (e.g., a plastic). Examples of the electrically insulating ceramic include an aluminum oxide sintered body, a mullite sintered body, a silicon carbide sintered body, an aluminum nitride sintered body, a silicon nitride sintered body, and a glass ceramic sintered body. Examples of the resin include an epoxy resin, a polyimide resin, an acrylic resin, a phenol resin, and a fluorine-based resin. Examples of the fluorine-based resin include a polyester resin and a tetrafluoroethylene resin.

The substrate 1 is not limited to a single layer, but can be a layered structure with a plurality of layers. When the substrate 1 has a layered structure with a plurality of layers, each of the plurality of layers may be made of the above-described material. In FIG. 1B, the substrate 1 has a layered structure having six layers. However, the number of layers of the substrate 1 is not limited to six, and may be one or more and five or less, or may be seven or more. In FIG. 1B, an opening 14 in which the electronic element 102 and the like are accommodated is formed in the substrate 1. However, the substrate 1 may have a shape (for example, a flat plate) in which the opening 14 is not formed.

The size of the substrate 1 in a plan view is, for example, from 0.3 mm to 10 cm. Examples of the shape of the substrate 1 in a plan view include a square and a rectangle. The thickness of the substrate 1 is, for example, 0.2 mm or more.

An electrode may be provided on the surface of the substrate 1. The electrode may electrically connect the electronic element mounting substrate 101 to an external circuit board, or may electrically connect the electronic device 201 to an external circuit board.

Inside the substrate 1, internal wiring formed between a plurality of layers and a through-hole conductor vertically connecting the internal wiring may be provided. The internal wiring and the through-hole conductor may be exposed on the surface of the substrate 1. An electrical connection between the electrode and another member may be realized by the internal wiring and the through-hole conductor.

The electronic element mounting substrate 101 may have a metallized layer. For example, the metallized layer is provided on the surface of the substrate 1, and more specifically, is provided in the mounting region 13 of the substrate 1. The metallized layer can be electrically connected to the electronic element 102.

When the substrate 1 is made of an electrically insulating ceramic, the metallized layer is made of, for example, any one of tungsten (W), molybdenum (Mo), manganese (Mn), silver (Ag), and copper (Cu), or an alloy containing at least one of them. When the substrate 1 is made of a resin, the metallized layer is made of, for example, any one of copper, gold (Au), aluminum (Al), nickel (Ni), molybdenum, and titanium (Ti), or an alloy containing at least one of these metals. The same applies to the electrode, the internal wiring, the through-hole conductor, and the first electrode pads 2a to 2e.

The first electrode pads 2a to 2e correspond to a plurality of protruding portions according to the present disclosure. The first electrode pads 2a to 2e are located on the lower surface 12 of the substrate 1. and more specifically, are provided on a surface of the substrate 1 on the opposite side to the mounting region 13. The number of first electrode pads provided on the electronic element mounting substrate 101 is not limited to five in the same row, and may be two or more and four or less in the same row, or may be six or more in the same row.

The first metal films 3a to 3e are located on lower surfaces (second lower surfaces) of the first electrode pads 2a to 2e, respectively, and more specifically, are provided on the lower surfaces of the first electrode pads 2a to 2e. That is, the first electrode pads 2a to 2e and the first metal films 3a to 3e have a one-to-one correspondence.

At least two of the first metal films 3a to 3e may be connected to each other. As long as the electronic element mounting substrate 101 includes at least one of the first metal films 3a to 3e, the other films may be omitted. From these forms, the number of first metal films may be one. Of course, the number of first metal films may be two or more.

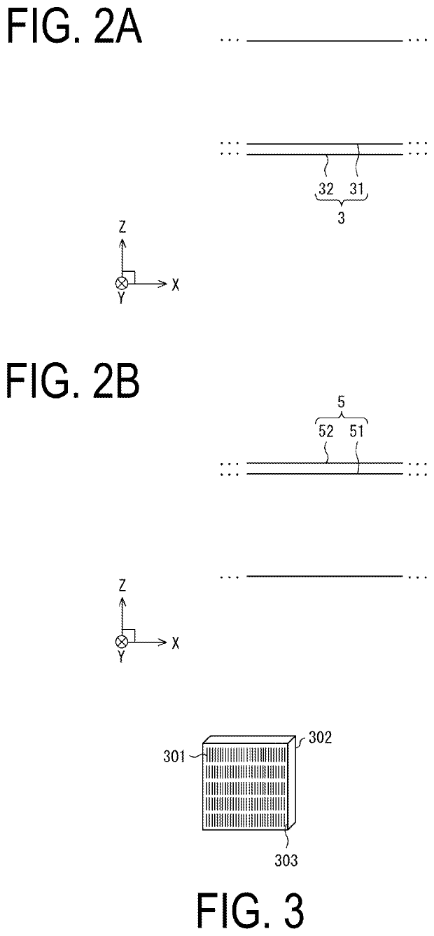

FIG. 2A is a cross-sectional view illustrating the layered structure in the first metal film 3, and FIG. 2B is a cross-sectional view illustrating the layered structure in a second metal film 5. The first metal film 3 is any one of the first metal films 3a to 3e, and the second metal film 5 is any one of the second metal films 5a and 5b.

As illustrated in FIG. 2A, the first metal film 3 includes a nickel coating 31 and a gold coating 32. The nickel coating 31 contains nickel as a main component, and is provided on the substrate 1 side with respect to the gold coating 32. The film thickness of the nickel coating 31 is, for example, from 0.03 μm to 3.0 μm. The gold coating 32 contains gold as a main component, and is provided on the opposite side to the substrate 1 with respect to the nickel coating 31 and covers at least a part of the nickel coating 31. That is, the gold coating 32 may cover the entirety of the nickel coating 31, or may cover a part of the nickel coating 31. The film thickness of the gold coating 32 is, for example, from 0.03 μm to 0.30 μm. The first metal film 3 preferably has a layered structure, but may have a single-layer structure. The same applies to the second metal film 5 described below.

The electronic element 102 is fixed on the mounting region 13. Examples of the electronic element 102 include a CCD-type imaging element, a CMOS-type imaging element, a light emitting element such as an LED or an LD, and an integrated circuit. CCD is an abbreviation of “Charge Coupled Device”. CMOS is an abbreviation of “Complementary Metal Oxide Semiconductor”. LED is an abbreviation of “Light Emitting Diode”. LD is an abbreviation of “Laser Diode”. The electronic element 102 is connected to the mounting region 13 via the connection material 103. Examples of the material of the connection material 103 include silver epoxy and thermosetting resin.

The lid body 104 is fixed to the upper surface of the substrate 1 and covers the electronic element 102. In a case where the electronic element 102 is any one of the imaging element and the light emitting element exemplified above, as an example of a material of the lid body 104, a material having high transparency such as a glass material is exemplified. In the case where the electronic element 102 is the integrated circuit exemplified above, examples of the material of the lid body 104 include a metal material and an organic material.

A frame-shaped body surrounding the electronic element 102 and supporting the lid body 104 may be provided on the upper surface of the electronic element mounting substrate 101. The frame-shaped body need not be provided in the electronic element mounting substrate 101. The material of the frame-shaped body and the material of the substrate 1 may be the same or different.

The lid bonding material 105 bonds the substrate 1 and the lid body 104. Examples of the material of the lid bonding material 105 include a thermosetting resin, low-melting-point glass, and a brazing material made of a metal component. When a frame-shaped body made of a material different from that of the substrate 1 is provided on the electronic element mounting substrate 101, the lid bonding material 105 may be made of the same material as that of the frame-shaped body. At this time, by providing the lid bonding material 105 to be thick, the lid bonding material 105 can have a function of bonding the substrate 1 and the lid body 104 and can function as a frame-shaped body that supports the lid body 104. In a case where a frame-shaped body made of the same material as the substrate 1 is provided in the electronic element mounting substrate 101, the frame-shaped body and the lid body 104 may be configured as the same member.

Production Method

An example of a method for manufacturing the electronic element mounting substrate 101 and the electronic device 201 of the present embodiment will be described. An example of the manufacturing method described below is a method of manufacturing the substrate 1 using a multi-piece wiring substrate.

(a) First, a ceramic green sheet constituting the substrate 1 is formed. For example, in order to obtain the substrate 1 made of an aluminum oxide (Al₂O₃)-based sintered body, a powder of, for example, silica (SiO₂), magnesia (MgO), or calcia (CaO) is added as a sintering aid to Al₂O₃ powder. Further, a suitable binder, solvent, and plasticizer are added, and then a mixture thereof is kneaded to form a slurry. Then, multi-piece ceramic green sheets are obtained by a formation method, such as a doctor blade method or a calendar roll method.

When the substrate 1 is made of, for example, a resin, the substrate 1 can be formed by a transfer molding method, an injection molding method, pressing with a mold, or the like, using a mold that can be molded into a predetermined shape. The substrate 1 may be made of a base material made of glass fibers impregnated with a resin, such as a glass epoxy resin. In this case, the substrate 1 can be formed by impregnating a base material made of glass fibers with a precursor of an epoxy resin and thermally curing the epoxy resin precursor at a predetermined temperature.

(b) Next, by a screen printing method or the like, a metal paste is applied to or made to fill portions of the ceramic green sheet obtained in the step (a) where the electrode pads, the internal wiring electrical conductor and/or the internal through-hole conductor are to be formed. This metal paste is created so as to have appropriate viscosity by adding a suitable solvent and binder to a metal powder formed of the above-described metal materials, and kneading the mixture. The metal paste may contain glass or ceramics in order to increase the bonding strength with the substrate 1.

When the substrate 1 is made of a resin, the electrode pads, the internal wiring electrical conductor and/or the internal through-hole conductor can be formed by a sputtering method, a vapor deposition method, or the like. The above may be manufactured by using a plating method after providing a metal film on the surface.

(c) Next, the above-described green sheet is processed by using a die or the like. Here, in a case where the substrate 1 has an opening portion, a notch, or the like, the opening portion, the notch, or the like may be formed at a predetermined position on the green sheets to be the substrate 1.

(d) Next, the ceramic green sheets to be the respective insulating layers of the substrate 1 are layered and pressed. In this manner, green sheets to be the insulating layers may be layered to fabricate a ceramic green sheet layered body to be the substrate 1. At this time, by using a die, punching, a laser, or the like. an opening portion may be provided at a predetermined position on the ceramic green sheets of a plurality of layers that have been layered

(e) Next, the ceramic green sheet layered body is fired at a temperature of about 1500° C. to 1800° C. to obtain a multi-piece wiring substrate in which a plurality of substrates 1 are arrayed. In this step, the above-described metal paste is fired simultaneously with the ceramic green sheets to be the substrate 1 to form the electrode pads, the internal wiring electrical conductor, and/or the internal through-hole conductor.

(f) Next, the multi-piece wiring substrate obtained by firing is divided into a plurality of substrates 1. For this division, a method in which a dividing groove is formed in the multi-piece wiring substrate along a portion to be the outer edge of the substrate 1, and the multi-piece wiring substrate is broken and divided along the dividing groove can be used, or a method in which the multi-piece wiring substrate is cut along a portion to be the outer edge of the substrate 1 by a slicing method or the like can be used. The dividing grooves can be formed by cutting into the multi-piece wiring substrate to a depth smaller than the thickness of the multi-piece wiring substrate by using a slicing device after firing. The dividing grooves may be formed by pressing a cutter blade against the ceramic green sheet layered body for the multi-piece wiring substrate or by cutting the ceramic green sheet layered body with a slicing device to a depth smaller than the thickness of the ceramic green sheet layered body. Before or after the multi-piece wiring substrate is divided into the plurality of substrates 1, the electrode pads, the internal wiring electrical conductor, and the internal through-hole conductor may be plated thereon.

(g) Next, the electronic element 102 is mounted on the mounting region 13 of the substrate 1. The electronic element 102 is electrically bonded to the substrate 1 by a connection member such as wire bonding. At this time, the electronic element 102 or the substrate 1 is provided with the connection material 103 or the like and fixed to the substrate 1. Alternatively, the lid body 104 may be bonded after the electronic element 102 is mounted on the substrate 1.

the electronic device 201 can be fabricated by fabricating the substrate 1 and mounting the electronic element 102 as in the steps (a) to (g) described above. The order of the steps (a) to (g) is not specified as long as it is a workable order.

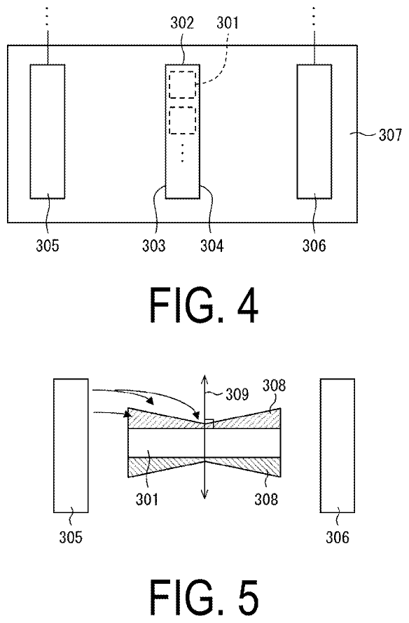

All the steps for obtaining the electronic element mounting substrate 101 from the multi-piece wiring substrate have been described above, and the plating method will be described in detail below. FIG. 3 is a view illustrating an example of a method of providing the gold coating 32 on the surface of the nickel coating 31, and is a perspective view illustrating a step of packing an intermediate body 301 of the electronic element mounting substrate 101 in a jig 302. FIG. 4 is a view illustrating an example of a method of providing the gold coating 32 on the surface of the nickel coating 31, and is a front view illustrating a step of plating the intermediate body 301 packed in the jig 302. The intermediate body 301 includes the nickel coating 31 similarly to the electronic element mounting substrate 101, and, unlike the electronic element mounting substrate 101, does not include the gold coating 32.

As an example of a method of providing the gold coating 32 on the surface of the nickel coating 31 (covering at least a part of the nickel coating 31), a method including the steps illustrated in FIGS. 3 and 4 is considered.

In the step illustrated in FIG. 3, the intermediate body 301 is packed in a jig 302. The outline of the jig 302 may be a rectangular parallelepiped as illustrated in FIG. 3. At this time, in the jig 302, a large number of spaces are formed along the normal direction of a pair of surfaces 303 and 304 (see FIG. 4) having the largest area among the surfaces constituting the rectangular parallelepiped. Each of the plurality of spaces is filled with the intermediate body 301. The number of spaces is, for example, about 250.

In the step illustrated in FIG. 4, first, the jig 302 filled with the intermediate body 301 and gold electrodes 305 and 306 are placed in a gold complex bath 307. Then, the surfaces 303 and 304 are made to oppose the gold electrodes 305 and 306, respectively, and the intermediate body 301 packed in the jig 302 is subjected to plating to provide the gold coating 32 on the intermediate body 301.

After the step illustrated in FIG. 4, the intermediate body 301 provided with the gold coating 32 is subjected to cleaning. At this time, the intermediate body 301 provided with the gold coating 32 may be removed from the jig 302 and cleaned; however, the intermediate body 301 is preferably cleaned while the intermediate body 301 is packed in the jig 302. In other words, it is preferable that the intermediate body 301 provided with the gold coating 32 be cleaned together with the jig 302 (without removing the intermediate body 301 provided with the gold coating 32 from the jig 302). Thus, a step of packing the intermediate body 301 provided with the gold coating 32 in a jig different from the jig 302 can be omitted, whereby the number of manufacturing steps of the electronic element mounting substrate 101 can be reduced.

FIG. 5 is a top view illustrating a trend 308, which is rough, of the film thickness distribution of the gold coating 32 provided on the intermediate body 301 in the step illustrated in FIG. 4. The trend 308 indicates a trend that the film thickness of the gold coating 32 provided on the intermediate body 301 increases as the thickness from the intermediate body 301 increases. In the step illustrated in FIG. 4, the intermediate body 301 is disposed such that a normal direction 309 of the upper surface and the lower surface of the intermediate body 301 is substantially perpendicular to the direction in which the gold electrode 305 and the gold electrode 306 are arranged (the horizontal direction in the drawing). According to the step illustrated in FIG. 4, the trend 308 includes two components (1) and (2) to be described below.

As another method of fabricating the first metal film 3 of the electronic element mounting substrate 101 of the present embodiment, for example, a method of fabricating the first metal film 3 by coating plating by an electrolytic plating method is exemplified. In the formation of the plating film by the electrolytic plating method, changing the resistance of the electrolytic plating pattern through which a current is passed can be contemplated. For example, the first metal film 3 may be fabricated by decreasing the electrical resistance of the electrolytic plating pattern on a side where the plating film is thickened and increasing the electrical resistance of the other side. For example, in the formation of the plating film by the electrolytic plating method, the first metal film may be fabricated by increasing the current on the side where the plating film is thickened.

(1) The film thickness of the gold coating 32 provided on the intermediate body 301 tends to monotonically decrease with increasing distance to the gold electrode 305.

(2) The film thickness of the gold coating 32 provided on the intermediate body 301 tends to monotonically decrease with increasing distance to the gold electrode 306.

In the electronic element mounting substrate 101, the first metal films 3a to 3e have surfaces 33a to 33e inclined with respect to the lower surface 12 of the substrate 1, respectively.

The surfaces 33a to 33e are not planes substantially parallel to the lower surface 12 of the substrate 1. Accordingly, the occurrence of scratches in a wide range of the surfaces 33a to 33e due to contact of an object in the wide range of the surfaces 33a to 33e can be reduced.

The surface area of the first metal films 3a to 3e is increased. Therefore, the solder can be firmly fixed to the first metal films 3a to 3e.

In the first metal film 3a, the thickness of the first metal film 3a monotonically decreases in a direction D1 from the peak thickness portion 34a having a maximum thickness toward the inside of the substrate 1 in a plan view of the substrate 1. A specific example of the component from which the monotonic decrease is derived is any one of the components (1) and (2). The direction D1 is merely a direction, and the start point of the monotonic decrease is the peak thickness portion 34a, but an end point thereof may be anywhere up to the end portion of the first metal film 3a on the opposite side to the peak thickness portion 34a.

The peak thickness portion 34a may have not only a dotted shape but also a linear shape. When the peak thickness portion 34a has a linear shape, the direction D1 may be different depending on which point on the peak thickness portion 34a is selected. When the peak thickness portion 34a has a linear shape, a plurality of directions D1 different from each other may be defined for a plurality of points on the peak thickness portion 34a, and the thickness of the first metal film 3a may monotonically decrease in the plurality of directions D1.

As a result, the components (1) and/or (2) in the example illustrated in FIGS. 3 and 4 can be effectively utilized to realize the surface 33a.

The monotonic decrease is the same for the first metal films 3b to 3e. The monotonic decrease is the same even when the first metal films 3a to 3e are regarded as one first metal film.

The electronic element mounting substrate 101 includes a plurality of first metal films 3a to 3e having surfaces 33a to 33e inclined substantially parallel to each other in a cross-sectional view (a cross-sectional view in the thickness direction of the substrate). The surfaces 33a to 33e of the plurality of first metal films 3a to 3e are inclined on the straight line L1 (on the same straight line) in the cross-sectional view. Here, “substantially parallel” means that the surfaces 33a to 33e are preferably strictly parallel to each other, but a part of the surfaces 33a to 33e may be slightly inclined with respect to the rest. Here, the “straight line L1” is a straight line along each of the surfaces 33a to 33e. At this time, in a case where each of the surfaces 33a to 33e is not a straight line in the cross-sectional view, for example, a straight line connecting at least the peak thickness portions of the surfaces 33a to 33e may be the “straight line L1”.

As a result, the components (1) and/or (2) in the example illustrated in FIGS. 3 and 4 can be effectively utilized to realize the surfaces 33a to 33e.

In a cross-sectional view in the thickness direction of the substrate 1, the shape of the first metal film 3a is substantially trapezoidal. In this case, since the first metal film 3a is not sharp, the likelihood that an object in contact with the first metal film 3a is greatly damaged can be reduced. The same applies to the first metal films 3b to 3e.

On the other hand, as illustrated in FIG. 1C, the shape of the first metal film 3a may be substantially triangular in a cross-sectional view in the thickness direction of the substrate 1. In this case, since the inclination angle of the surface 33a with respect to the lower surface 12 of the substrate 1 can be made steep, the occurrence of scratches in a wide range of the surface 33a can be further reduced. The same applies to the first metal films 3b to 3e.

The thickness T1, which is the maximum value of the thickness of the first metal film 3a, is from 0.06 μm to 3.30 μm. Specifically, the maximum value of the film thickness of the nickel coating 31 in the first metal film 3a is from 0.03 μm to 3.0 μm, and the maximum value of the film thickness of the gold coating 32 in the first metal film 3a is from 0.03 μm to 0.30 μm. The same applies to the first metal films 3b to 3e.

The thickness T2, which is the minimum value of the thickness of the first metal film 3e, may be, for example, 50 to 99% of the thickness T1, which is the maximum value of the thickness of the first metal film 3a.

As illustrated in FIG. 1B, points Ta and Tb of the first metal film 3a are defined from the upstream side of the direction D1 described above. At this time, the film thickness of the first metal film 3a satisfies the relation of point Tb<point Ta.

When the first metal films 3a to 3e are regarded as one first metal film, as illustrated in FIG. 1B, points Ta to Tj of the first metal film are defined from the upstream side of the direction D1 described above. At this time, the film thickness of the first metal film satisfies the relation of point Tj<point Ti<point Th<point Tg<point Tf<point Te<point Td<point Tc<point Tb<point Ta.

### Second Embodiment

Hereinafter, the electronic device 201 according to a second embodiment of the present disclosure will be described.

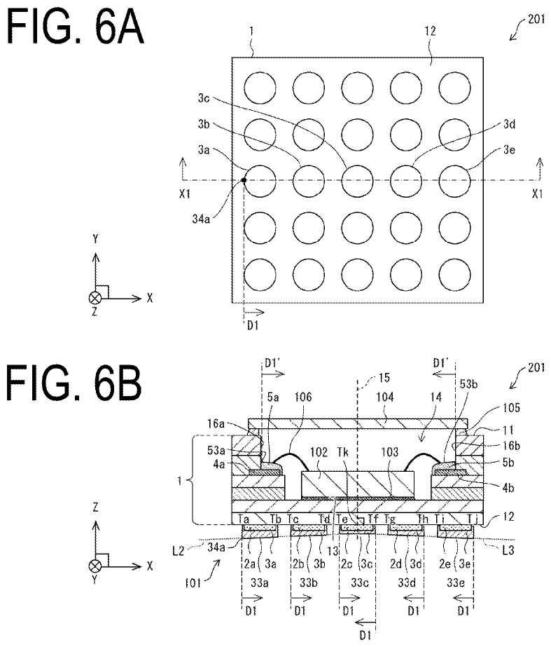

FIG. 6A is a bottom view illustrating an appearance of the electronic device 201 according to the second embodiment of the present disclosure, and FIG. 6B is a vertical cross-sectional view corresponding to the line X1-X1 in FIG. 6A.

The electronic element mounting substrate 101 of the electronic device 201 according to the second embodiment of the present disclosure includes a plurality of first metal films 3a to 3e having surfaces 33a to 33e inclined at positive and negative opposite inclinations with respect to the normal line 15 of the substrate 1 in a cross-sectional view in the thickness direction of the substrate 1. In FIG. 6B, the inclination angle of the surfaces 33a to 33e with respect to the normal line 15 is less than 90°, the clockwise inclination with respect to the normal line 15 is a positive inclination, and the counterclockwise inclination with respect to the normal line 15 is a negative inclination. The surfaces 33a to 33e of the plurality of first metal films 3a to 3e are inclined on two straight lines L2 and L3 that are substantially line-symmetrical to each other with respect to the normal line 15 of the substrate 1 in the cross-sectional view. Here, the term “substantially line-symmetrical” means that the straight line L2 and the straight line L3 are preferably strictly line-symmetrical to each other, but the straight line L2 may be slightly deviated from the line symmetry with respect to the straight line L3. Here, the “straight line L2” and the “straight line L3” are straight lines along the respective surfaces of the plurality of first metal films 3a to 3e, which are inclined in positive and negative directions opposite to each other with respect to the normal line 15. At this time, if the “straight line L2” and the “straight line L3” are not straight lines, they may be straight lines connecting at least the thickest portions. The normal line 15 of the substrate 1 is a straight line orthogonal to the upper surface and the lower surface of the substrate 1, and is a straight line in the Z direction because the upper surface and the lower surface of the substrate 1 can be approximated by the XY plane.

In the electronic device 201 according to the second embodiment of the present disclosure, it can be said that the direction D1 defined in the first metal films 3a and 3b and the direction D1 defined in the first metal films 3d and 3e are opposite to each other in the cross-sectional view. It can be said that the direction D1 defined in the left half of the first metal film 3c is the same direction as defined in the first metal films 3a and 3b, and the direction D1 defined in the right half of the first metal film 3c is the same direction as defined in the first metal films 3d and 3e.

As a result, the components (1) and (2) in the example illustrated in FIGS. 3 and 4 can be effectively utilized to realize the surfaces 33a to 33e.

When the first metal films 3a to 3e are regarded as one first metal film, as illustrated in FIG. 6B, points Ta to Tj of the first metal film are defined at the same positions as those illustrated in FIG. 1B. A point on the normal 15 to the first metal film 3c is defined as a point Tk. At this time, the film thickness of the first metal film satisfies the relations of point Tk<point Te<point Td<point Tc<point Tb<point Ta and point Tk<point Tf<point Tg<point Th<point Ti<point Tj.

### Third Embodiment

Hereinafter, the electronic device 201 according to a third embodiment of the present disclosure will be described.

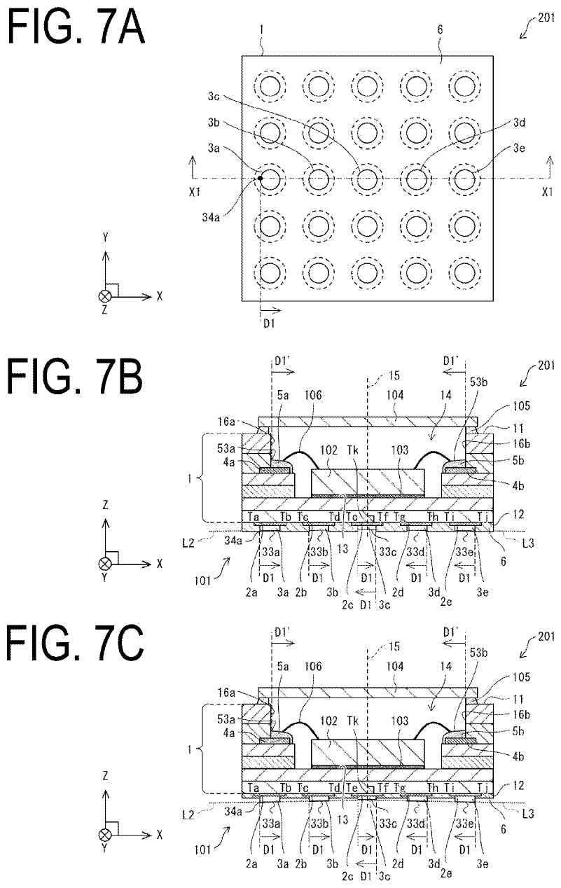

FIG. 7A is a bottom view illustrating the appearance of the electronic device 201 according to the third embodiment of the present disclosure, FIG. 7B is a vertical cross-sectional view corresponding to the line X1-X1 in FIG. 7A, and FIG. 7C is a variation of FIG. 7B.

In the electronic device 201 according to the third embodiment of the present disclosure, the electronic element mounting substrate 101 includes a thin film 6. The thin film 6 is located between two adjacent ones of the plurality of first metal films 3a to 3e at least on the lower surface 12 of the substrate 1. The thin film 6 is provided covering the lower surface 12 of the substrate 1. Examples of the thin film 6 include an alumina coat and an inorganic film. Thus, the lower surface 12 of the substrate 1 can be protected by the thin film 6.

According to FIG. 7B, the thin film 6 protrudes from at least one of two adjacent first metal films 3a to 3e with the lower surface 12 of the substrate 1 as a reference. The two adjacent ones of the plurality of first metal films 3a to 3e are any of the first metal films 3a and 3b, the first metal films 3b and 3c, the first metal films 3c and 3d, and the first metal films 3d and 3e. At least one of two adjacent ones of the plurality of first metal films 3a to 3e is at least one first metal film of the two adjacent ones of the plurality of first metal films 3a to 3e. In FIG. 7B, the thin film 6 protrudes from all of the plurality of first metal films 3a to 3e with the lower surface 12 of the substrate 1 as a reference. Here, the fact that the thin film 6 protrudes from the at least one first metal film with the lower surface 12 of the substrate 1 as a reference means that the lower surface of the thin film 6 is located below the at least one first metal film. The above configuration makes it difficult for objects to come into contact with the first metal films 3a to 3e.

According to FIG. 7C, at least one of two adjacent ones of the plurality of first metal films 3a to 3e protrudes from the thin film 6 with the lower surface 12 of the substrate las a reference. In FIG. 7C, all of the plurality of first metal films 3a to 3e protrude from the thin film 6 with the lower surface 12 of the substrate 1 as a reference. Here, the fact that the at least one first metal film protrudes from the thin film 6 with the lower surface 12 of the substrate 1 as a reference means that the lower surface of the at least one first metal film is located below the thin film 6. According to the above configuration, when an electronic element or the like is connected to the first metal films 3a to 3e from the outside of the electronic element mounting substrate 101, the likelihood that the thin film 6 hinders the connection can be reduced.

According to FIGS. 7B and 7C, a part of the thin film 6 is located on a part of the lower surface (third lower surface) of each of the first electrode pads 2a to 2e. According to the above configuration, a part of the lower surface of each of the first electrode pads 2a to 2e can be protected by the thin film 6.

The electronic element mounting substrate 101 of the electronic device 201 according to the third embodiment of the present disclosure includes a plurality of first metal films 3a to 3e having surfaces 33a to 33e inclined at positive and negative opposite inclinations with respect to the normal line 15 of the substrate 1 in a cross-sectional view in the thickness direction of the substrate 1. In FIGS. 7B and 7C, the inclination angle of the surfaces 33a to 33e with respect to the normal line 15 is less than 90°, the clockwise inclination with respect to the normal line 15 is a positive inclination, and the counterclockwise inclination with respect to the normal line 15 is a negative inclination. The surfaces 33a to 33e of the plurality of first metal films 3a to 3e are inclined on two straight lines L2 and L3 that are substantially line-symmetrical to each other with respect to the normal line 15 of the substrate 1 in the cross-sectional view.

When the first metal films 3a to 3e are regarded as one first metal film, as illustrated in FIGS. 7B and 7C, points Ta to Tk of the first metal film are defined at the same positions as those illustrated in FIG. 6B. At this time, the magnitude relationship between the points Ta to Tk is the same between FIG. 6B and FIGS. 7B and 7C.

Second Metal Film

Hereinafter, the second electrode pads 4a and 4b, the second metal films 5a and 5b, and the bonding wire 106 will be described with reference to the above-described embodiments. As the configuration of each of the electronic element 102, the connection material 103, the lid body 104, the lid bonding material 105, the substrate 1, the first electrode pads 2a to 2e, and the first metal films 3a to 3e, the configuration illustrated in each of the embodiments described above can be appropriately used.

The second electrode pads 4a and 4b are located on the surface of substrate 1, and more specifically, are provided on the side of the substrate 1 on which the electronic element 102 is to be mounted (upper surface of substrate 1). The second electrode pads 4a and 4b are electrically connected to the electronic element 102. In each of the above-described embodiments, the number of the second electrode pads is two, but is not limited thereto, and the number of the second electrode pads may be one, or may be three or more.

An electrode may be provided on the surface of the substrate 1. The electrode may electrically connect the electronic element mounting substrate 101 to an external circuit board, or may electrically connect the electronic device 201 to an external circuit board.

Inside the substrate 1, internal wiring formed between a plurality of layers and a through-hole conductor vertically connecting the internal wiring may be provided. The internal wiring and the through-hole conductor may be exposed on the surface of the substrate 1. The electrode may be electrically connected to the second electrode pads 4a and/or 4b by the internal wiring and the through-hole conductor.

When the substrate 1 is made of an electrically insulating ceramic, the second electrode pads 4a and 4b are made of, for example, any one of tungsten, molybdenum, manganese, silver, and copper, or an alloy containing at least one of the aforementioned. When the substrate 1 is made of a resin, the second electrode pads 4a and 4b are made of, for example, any one of copper, gold, aluminum, nickel, molybdenum, and titanium, or an alloy containing at least one of the aforementioned. The same applies to each of the electrode, the internal wiring, and the through-hole conductor.

The second metal films 5a and 5b are located on the surface of the substrate 1. To be more specific, the second metal films 5a and 5b are provided on the surfaces of the second electrode pads 4a and 4b located on the surface of the substrate 1. The second metal film is provided on the surface of each second electrode pad.

As illustrated in FIG. 2B, the second metal film 5, which is any one of the second metal films 5a and 5b, includes a nickel coating 51 and a gold coating 52. The nickel coating 51 contains nickel as a main component, and is provided on the substrate 1 side with respect to the gold coating 52. The film thickness of the nickel coating 51 is, for example, from 0.03 μm to 3.0 μm. The gold coating 52 contains gold as a main component, and is provided on the opposite side to the substrate 1 with respect to the nickel coating 51, covering at least a part of the nickel coating 51. That is, the gold coating 52 may cover the entirety of the nickel coating 51, or may cover a part of the nickel coating 51. The film thickness of the gold coating 52 is, for example, from 0.03 μm to 0.30 μm. As described above, the second metal film 5 preferably has a layered structure, but may have a single-layer structure.

The bonding wire 106 is wiring for electrically connecting the second electronic element 102 and the second metal film 5 (and thus the electrode pad 4). Although not illustrated, the second electrode pad 4 is a convenient representation of one of the second electrode pads 4a and 4b corresponding to the second metal film 5.

In the above description with reference to FIGS. 3 to 5, the nickel coating 31 and the gold coating 32 may be regarded as the nickel coating 51 and the gold coating 52, respectively. Thus, the description with reference to FIGS. 3 to 5 can be interpreted as an example of a method of providing the gold coating 52 on the surface of the nickel coating 51 (covering at least a part of the nickel coating 51).

The second metal films 5a and 5b located on the surface of the substrate 1 have surfaces 53a and 53b inclined with respect to the surface of the substrate 1, respectively. The surface of the substrate 1 refers to, for example, an upper surface of the substrate 1 or a surface on which an element is to be mounted. Here, it can be said that the surfaces 53a and 53b being inclined with respect to the surface of the substrate 1 more specifically means that the surfaces 53a and 53b are inclined with respect to the internal wall surfaces 16a and 16b of the substrate 1, respectively. In the second metal films 5a and 5b, the thicknesses of the second metal films 5a and 5ba monotonically decrease in a direction D1′ that is the same as the direction D1 from the peak thickness portion 34a of the first metal film 3a having a maximum film thickness in the first metal film 3a toward the inside of the substrate 1 in the plan view of the substrate 1.

When the inclination directions of the second metal films 5a and 5b in the same row are constant, the angle formed with the capillaries is easily kept constant, and wire bonding can be stably performed. Variations in the position of the wire bond contact can be reduced. Therefore, wire bonding defects can be reduced.

Conclusion

An electronic element mounting substrate according to a first aspect of the present disclosure includes a substrate including an upper surface, a first lower surface, a mounting region located on the upper surface and on which an electronic element is to be mounted, and a plurality of protruding portions located on the first lower surface; and at least one first metal film located on a second lower surface that is a lower surface of the plurality of protruding portions, in which the first metal film includes a surface inclined with respect to the first lower surface.

The surface of the first metal film is not a plane substantially parallel to the lower surface of the substrate. Thus, the occurrence of scratches in a wide range of the surface of the first metal film due to contact of an object with the wide range of the surface of the first metal film can be reduced.

The surface area of the first metal film is increased. Therefore, solder can be firmly fixed to the first metal film.

According to an electronic element mounting substrate according to a second aspect of the present disclosure, in the first aspect, in the first metal film, a thickness of the first metal film monotonically decreases in a direction from a peak thickness portion having a maximum thickness toward an inner side of the substrate in a plan view of the substrate.

In the first or second aspect, an electronic element mounting substrate according to a third aspect of the present disclosure includes the first metal film in a plurality and the plurality of first metal films include surfaces inclined substantially parallel to each other in a cross-sectional view in a film thickness direction of the substrate.

According to an electronic element mounting substrate according to a fourth aspect of the present disclosure, in the third aspect, the surfaces of the plurality of first metal films are inclined on the same straight line in the cross-sectional view.

According to each of the above-described configurations, the surface of the first metal film can be realized by effectively utilizing the rough trend of the distribution of the film thickness of the first metal film.

In the first or second aspect, an electronic element mounting substrate according to a fifth aspect of the present disclosure includes the first metal film in a plurality and the plurality of first metal films include surfaces inclined at positive and negative opposite inclinations with respect to a normal line of the substrate in a cross-sectional view in a film thickness direction of the substrate.

According to an electronic element mounting substrate according to a sixth aspect of the present disclosure, in the fifth aspect, the surfaces of the plurality of first metal films are inclined on two straight lines that are substantially line-symmetrical to each other with respect to the normal line of the substrate in the cross-sectional view.

According to each of the above-described configurations, the surface of the first metal film can be realized by further effectively utilizing the rough trend of the distribution of the film thickness of the first metal film.

In any one of the first to sixth aspects, an electronic element mounting substrate according to a seventh aspect of the present disclosure further includes, on the first lower surface, a thin film located between two adjacent ones of the plurality of first metal films.

According to the above configuration, the lower surface of the substrate can be protected by the thin film.

According to an electronic element mounting substrate according to an eighth aspect of the present disclosure, in the seventh aspect, at least one of two adjacent ones of the plurality of first metal films protrudes from the thin film with respect to the first lower surface.

According to the above configuration, when an electronic element or the like is connected to the first metal films from the outside of the electronic element mounting substrate, the likelihood of the thin film hindering the connection can be reduced.

According to an electronic element mounting substrate according to a ninth aspect of the present disclosure, in the seventh aspect, the thin film protrudes from at least one of two adjacent ones of the plurality of first metal films with respect to the first lower surface.

The above configuration makes it difficult for objects to come into contact with the first metal films.

According to an electronic element mounting substrate according to a tenth aspect of the present disclosure, in any one of the seventh to ninth aspects, a portion of the thin film is located on a portion of a third lower surface that is a lower surface of the protruding portion.

According to the configuration, a part of the lower surface of the protruding portion can be protected by the thin film.

According to an electronic element mounting substrate according to an eleventh aspect of the present disclosure, in any one of the first to tenth aspects, a shape of the first metal film is substantially triangular or substantially trapezoidal in a cross-sectional view in a film thickness direction of the substrate.

When the shape of the first metal film is a substantially triangular shape in a cross-sectional view in the film thickness direction of the substrate, the inclination angle of the surface of the first metal film with respect to the lower surface of the substrate can be made steep, and thus the occurrence of scratches in a wide range of the surface of the first metal film can be further reduced. In the case where the shape of the first metal film is a substantially trapezoidal shape in the cross-sectional view, the first metal film is not sharp. Therefore, the likelihood of an object in contact with the first metal film being greatly damaged can be reduced.

According to an electronic element mounting substrate according to a twelfth aspect of the present disclosure, in any one of the first to eleventh aspects, a maximum value of a film thickness of the first metal film is from 0.06 μm to 3.30 μm.

According to an electronic element mounting substrate according to a thirteenth aspect of the present disclosure, in any one of the first to twelfth aspects, the first metal film includes a nickel coating containing nickel as a main component; and a gold coating provided covering at least a part of the nickel coating, the gold coating containing gold as a main component, wherein a maximum value of a film thickness of the gold coating in the first metal film is from 0.03 μm to 0.30 μm. The main component may be, for example, a component which is contained in an amount of 50% or more of the whole, or may be a component which is contained in the largest amount among the all of the components.

According to a fourteenth aspect of the present disclosure, the electronic element mounting substrate according to any one of the first to thirteenth aspects further includes a second metal film located on a surface of the substrate, wherein the second metal film has a surface inclined with respect to the surface of the substrate.

According to an electronic element mounting substrate according to a fifteenth aspect of the present disclosure, in the fourteenth aspect, in the second metal film, a thickness of the second metal film monotonically decreases in the same direction as a direction from a peak thickness portion of the first metal film having a maximum thickness in the first metal film toward an inner side of the substrate in a plan view of the substrate.

The present disclosure is not limited to each of the embodiments described above, and various modifications can be made within the scope indicated by the claims, and an embodiment obtained by appropriately combining technical means disclosed in different embodiments is also included in a technical scope of the present disclosure.

### REFERENCE SIGNS

1 Substrate
2a to 2e First electrode pad (protruding portion)
3, 3a to 3e First metal film
4a 4b Second electrode pad
5, 5a, 5b Second metal film
6 Thin film
11 Upper surface of substrate
12 Lower surface of substrate (first lower surface)
13 Mounting region
14 Opening
15 Normal line
31, 51 Nickel coating
32, 52 Gold coating
33a to 33e Surface of first metal film
34a Peak thickness portion
53a 53b Surface of second metal film
101 Electronic element mounting substrate
102 Electronic element
103 Connection material
104 Lid body
105 Lid bonding material
106 Bonding wire
201 Electronic device
301 Intermediate body
302 Jig
303, 304 Surface
305, 306 Gold electrode
307 Gold complex bath
308 Trend
309 Normal direction
D1 Direction from peak thickness portion toward inner side of substrate in plan view of substrate
D1′ Direction identical to direction D1
L1 to L3 Straight line
T1, T2 Thickness

1. An electronic element mounting substrate, comprising:
a substrate comprising an upper surface, a first lower surface, a mounting region located on the upper surface and on which an electronic element is to be mounted, and a plurality of protruding portions located on the first lower surface; and
at least one first metal film located on a second lower surface that is a lower surface of the plurality of protruding portions, wherein
the first metal film comprises a surface inclined with respect to the first lower surface.

2. The electronic element mounting substrate according to claim 1, wherein
in the first metal film, a thickness of the first metal film monotonically decreases in a direction from a peak thickness portion having a maximum thickness toward an inner side of the substrate in a plan view of the substrate.

3. The electronic element mounting substrate according to claim 1, wherein
the first metal film is provided in a plurality and the plurality of first metal films comprise surfaces inclined substantially parallel to each other in a cross-sectional view in a film thickness direction of the substrate.

4. The electronic element mounting substrate according to claim 3, wherein
the surfaces of the plurality of first metal films are inclined on the same straight line in the cross-sectional view.

5. The electronic element mounting substrate according to claim 1, wherein
the first metal film is provided in a plurality and the plurality of first metal films comprise surfaces inclined at positive and negative opposite inclinations with respect to a normal line of the substrate in a cross-sectional view in a film thickness direction of the substrate.

6. The electronic element mounting substrate according to claim 5, wherein
the surfaces of the plurality of first metal films are inclined on two straight lines that are substantially line-symmetrical to each other with respect to the normal line of the substrate in the cross-sectional view.

7. The electronic element mounting substrate according to claim 1, further comprising:
on the first lower surface, a thin film located between two adjacent ones of the plurality of first metal films.

8. The electronic element mounting substrate according to claim 7, wherein
at least one of two adjacent ones of the plurality of first metal films protrudes from the thin film with respect to the first lower surface.

9. The electronic element mounting substrate according to claim 7, wherein
the thin film protrudes from at least one of two adjacent ones of the plurality of first metal films with respect to the first lower surface.

10. The electronic element mounting substrate according to claim 7, wherein
a portion of the thin film is located on a portion of a third lower surface that is a lower surface of the protruding portion.

11. The electronic element mounting substrate according to claim 1, wherein
a shape of the first metal film is substantially triangular or substantially trapezoidal in a cross-sectional view in a film thickness direction of the substrate.

12. The electronic element mounting substrate according to claim 1, wherein
a maximum value of a film thickness of the first metal film is from 0.06 μm to 3.30 μm.

13. The electronic element mounting substrate according to claim 1, wherein
the first metal film comprises:
a nickel coating containing nickel as a main component; and
a gold coating provided covering at least a part of the nickel coating, the gold coating containing gold as a main component, and
a maximum value of a film thickness of the gold coating in the first metal film is from 0.03 μm to 0.30 μm.

14. The electronic element mounting substrate according to claim 1, further comprising:
a second metal film located on a surface of the substrate, wherein
the second metal film comprises a surface inclined with respect to the surface of the substrate.

15. The electronic element mounting substrate according to claim 14, wherein
in the second metal film, a thickness of the second metal film monotonically decreases in a direction identical to a direction from a peak thickness portion of the first metal film having a maximum thickness in the first metal film toward an inner side of the substrate in a plan view of the substrate.
